(19) United States
(12) Patent Application Publication
(10) Pub. No.: US 2013/0062606 A1
(43) Pub. Date: Mar. 14, 2013

(54) THIN FILM TRANSISTOR AND METHOD OF MANUFACTURING THE SAME

(71) Applicant: JIAN-SHIHN TSANG, Tu-Cheng (TW)

(72) Inventor: JIAN-SHIHN TSANG, Tu-Cheng (TW)

(73) Assignee: HON HAI PRECISION INDUSTRY CO., LTD., Tu-Cheng (TW)

(21) Appl. No.: 13/597,363

(22) Filed: Aug. 29, 2012

(30) Foreign Application Priority Data
Sep. 14, 2011 (TW) 100132925

(51) Int. Cl. H01L 29/786; H01L 21/336

(52) U.S. Cl. 257/57; 438/158; 257/E29.273; 257/E21.409

(57) ABSTRACT

A thin film transistor includes a substrate with a recess formed therein, a channel region received in the recess, a gate insulating layer formed on the channel region, a gate electrode formed on the gate insulating layer, and a source region and a drain region connecting the channel region, respectively. The gate insulating layer and the gate electrode are positioned between the source region and the drain region. The channel region is made of a nitride compound semiconductor. A method of manufacturing the thin film transistor is also provided.

### BACKGROUND

1. Technical Field

The disclosure generally relates to a semiconductor element and a method of manufacturing the semiconductor element, and more particularly to a thin film transistor and a method of manufacturing the thin film transistor.

2. Description of Related Art

Nowadays, thin film transistors have been widely used in display devices to make the display devices thinner and smaller. A typical thin film transistor includes a channel region, a source region formed at an end of the channel region and a drain region formed at an opposite end of the channel region. The channel region, the source region and the drain region are also called active layers. A gate electrode is formed on the channel region. A source electrode and a drain electrode are formed on the source region and the drain region, respectively. The thin film transistor is turned on or turned off by controlling a voltage applied to the gate electrode.

Generally, there are amorphous silicon type thin film transistor and polycrystalline type thin film transistor, according to the material of the active layers. Recent years, transparent conducting metal oxides such as ZnO are used in the active layers of the thin film transistor. The thin film transistor using transparent conducting metal oxides has an advanced electricity characteristic compared with the conventional thin film transistor such as amorphous silicon type thin film transistor. However, the transparent conducting metal oxides can be easily contaminated by plasma, etching solution, and photoresist during the processes of forming the active layers.

What is needed, therefore, is a thin film transistor and a method of manufacturing the same to overcome the above described disadvantages.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a cross-sectional view showing a thin film transistor in accordance with a first embodiment of the present disclosure.

FIG. 2 is a cross-sectional view showing a thin film transistor in accordance with a second embodiment of the present disclosure.

FIG. 3 is a cross-sectional view showing a thin film transistor in accordance with a third embodiment of the present disclosure.

FIG. 4 is a cross-sectional view showing a thin film transistor in accordance with a fourth embodiment of the present disclosure.

FIG. 5 is a cross-sectional view showing a thin film transistor in accordance with a fifth embodiment of the present disclosure.

FIG. 6 is a cross-sectional view showing a thin film transistor in accordance with a sixth embodiment of the present disclosure.

FIG. 7 is a flow-chart showing a method of manufacturing the thin film transistor in accordance with the second embodiment of the present disclosure.

FIG. 8 shows cross-sectional views of the thin film transistor obtained by different steps of the method shown in FIG. 7.

FIG. 9 is a flow-chart showing another method of manufacturing the thin film transistor in accordance with the second embodiment of the present disclosure.

FIG. 10 shows cross-sectional views of the thin film transistor obtained by different steps of the method shown in FIG. 9.

### DETAILED DESCRIPTION

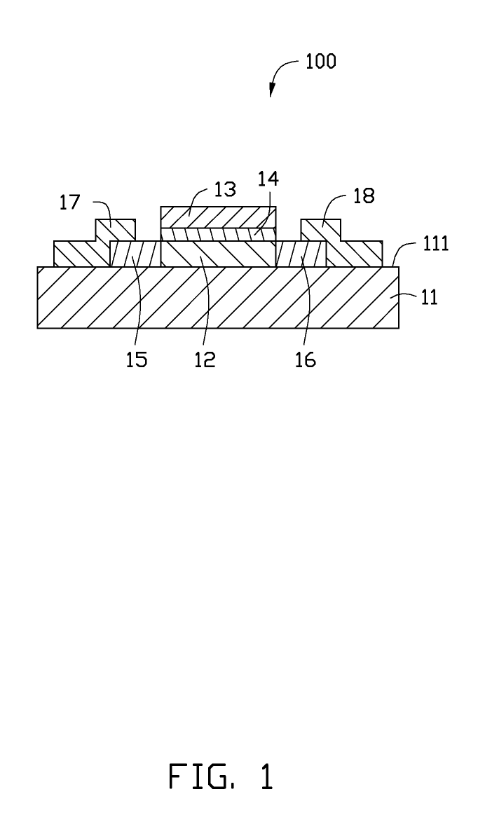

Referring to FIG. 1, a thin film transistor 100 in accordance with a first embodiment of the present disclosure is a top gate transistor. The thin film transistor 100 includes a substrate 11, a channel region 12 formed on the substrate 11, a gate insulating layer 14 formed on the channel region 12, a gate electrode 13 formed on the gate insulating layer 14, and a source region 15 and a drain region 16 formed on the substrate 11. The source region 15 and the drain region 16 are formed at two opposite ends of the channel region 12 to connect the channel region 12, respectively.

The substrate 11 is made of a material selected from a group consisting of glass, sapphire, quartz, silicon, polycarbonate and polymethyl methacrylate(PMMA). The substrate 11 has a top surface 111.

The channel region 12 is formed on the top surface 111 of the substrate 11.

The channel region 12 is made of a nitride compound semiconductor. In one embodiment, a material of the nitride compound semiconductor is represented by a formula of Al_{(1-x-y)}InₓGa_{y}N, wherein 0≦x≦1, 0≦y≦1. The nitride compound semiconductor has a large range of band gap and varies at the range of 1.9 eV-6.2 eV according to a composition of a doping element doped therein. The thin film transistor 100 having the channel region 12 formed with the nitride compound semiconductor has a higher conductivity; therefore, display devices using the thin film transistor 100 have a higher response speed, and also meet the requirement of high-definition and high capacity. A resistance of humidity and radiation of the thin film transistor 100 is also enhanced. In an alternative embodiment, during the forming process of the channel region 12 with the nitride compound semiconductor, elements H, C and O can be included in the nitride compound semiconductor. In addition, a material of the nitride compound semiconductor can be made of doped Al_{(1-x-y)}InₓGa_{y}N, wherein 0≦x≦1, and 0≦y≦1, and N-type elements such as Si or P-type elements such as Mg, Zn can be doped in the nitride compound semiconductor to form an N-type nitride compound semiconductor or a P-type nitride compound semiconductor. The nitride compound semiconductor can be amorphous, monocrystalline or polycrystalline according to forming conditions such as growing temperature, growing pressure and growing environment, to meet different requirements.

The source region 15 is formed at one end of the channel region 12, and the drain region 16 is formed at an opposite end of the channel region 12. In other words, the channel region 12 is sandwiched between the source region 15 and the drain region 16. Top surfaces of the channel region 12, the source region 15 and the drain region 16 are in a same plane.

The gate insulating layer 14 is overlapping on the top surface of the channel region 12. The gate electrode 13 is overlapping on a top surface of the gate insulating layer 14. Edges of the gate electrode 13 and the gate insulating layer 14 are in alignment with an edge of the channel region 12. The gate electrode 13 can be made of a material selected from Cu, Al, Ni, Ti, Cr, Mo, W and Ta, and made by a process of thin film deposition, lithography or etching. The gate insulating layer 14 is made of a material selected from a group consisting of SiOₓ, SiNₓ, SiO_{y}Nₓ, and made by a process of chemical vapor deposition (CVD).

A source electrode 17 is formed on the source region 15, and a drain electrode 18 is formed on the drain region 16. The source electrode 17 and the drain electrode 18 are used for connecting a power supply to provide electricity for the thin film transistor 100. A light doping area may be formed at a joint of the channel region 12 and the source region 15, or at a joint of the channel region 12 and the drain region 16. The light doping area can prevent the leakage of the electricity and thus enhance a stability of the thin film transistor 100.

Since the channel region 12 is formed of a nitride compound semiconductor material, the thin film transistor 100 has a higher stability to avoid to be affected in the subsequent processes such as etching. The thin film transistor 100 also has a higher electron mobility, whereby devices using the thin film transistor 100 have a higher response speed.

The channel region 12, the source region 15 and the drain region 16 acting as active layers can be formed on the substrate 11 by a process of CVD, pulse laser deposition, molecule beam epitaxy (MBE), physical vapor deposition (PVD), or sputtering. After the active layers being formed, the gate insulating layer 14 and the gate electrode 13 can be formed in series.

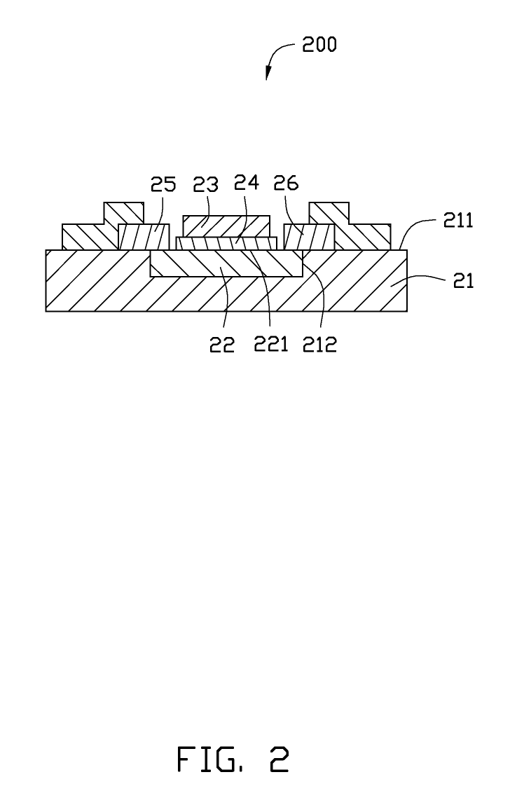

Referring to FIG. 2, a thin film transistor 200 in accordance with a second embodiment of the present disclosure is a top gate transistor. The thin film transistor 200 is similar to the thin film transistor 100, excepting a position of a channel region 22, a source region 25 and a drain region 26, and a structure of a gate insulating layer 24 and a gate electrode 23. In this embodiment, the thin film transistor 200 has a substrate 21. A recess 212 is formed in a top surface 211 of the substrate 21. The channel region 22 is positioned in the recess 212. A top surface 221 of the channel region 22 is coplanar with the top surface 211 of the substrate 21. The source region 25 and the drain region 26 are formed on the top surface 211 of the substrate 21. The source region 25 and the drain region 26 extend to connect the channel region 22 and cover two opposite edges of the top surface 221 of the channel region 22. The gate insulating layer 24 is formed on the top surface 221 of the channel region 22, and the gate electrode 23 is formed on the gate insulating layer 24 opposite to the channel region 22. The gate insulating layer 24 and the gate electrode 23 are positioned between the source region 25 and the drain region 26. The gate insulating layer 24 is spaced from the source region 25 and the drain region 26, with a gap defined therebetween, respectively. The gate electrode 23 has a smaller sized than the gate insulating layer 24, whereby edges of the gate insulating layer 24 are not covered by the gate electrode 23.

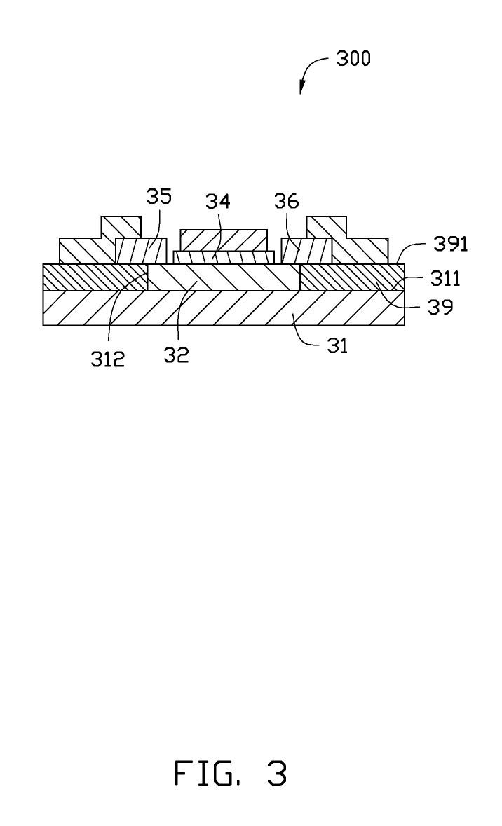

Referring to FIG. 3, a thin film transistor 300 in accordance with a third embodiment of the present disclosure is a top gate transistor. The thin film transistor 300 is similar to the thin film transistor 200, excepting a connecting structure of a substrate 31 and a channel region 32. In the third embodiment, the thin film transistor 300 further includes an adhering layer 39 formed on a top surface 311 of a substrate 31. The adhering layer 39 has a groove 312 formed therein and a portion of the top surface 311 is exposed due to the groove 312 of the adhering layer 39. The channel region 32 is then formed on the portion of the top surface 311 of the substrate 31 and received in the groove 312. A top surface of the channel region 32 and a top surface of the adhering layer 39 are coplanar to form a flattened surface 391 on which a source region 35, a drain region 36 and a gate insulating layer 34 are formed. Specifically, the gate insulating layer 34 is formed on the top surface of the channel region 32. The source region 35 and the drain region 36 are formed on the top surface of the adhering layer 39, and extend to connect the channel region 32 and cover two opposite edges of the top surface of the channel region 32, respectively.

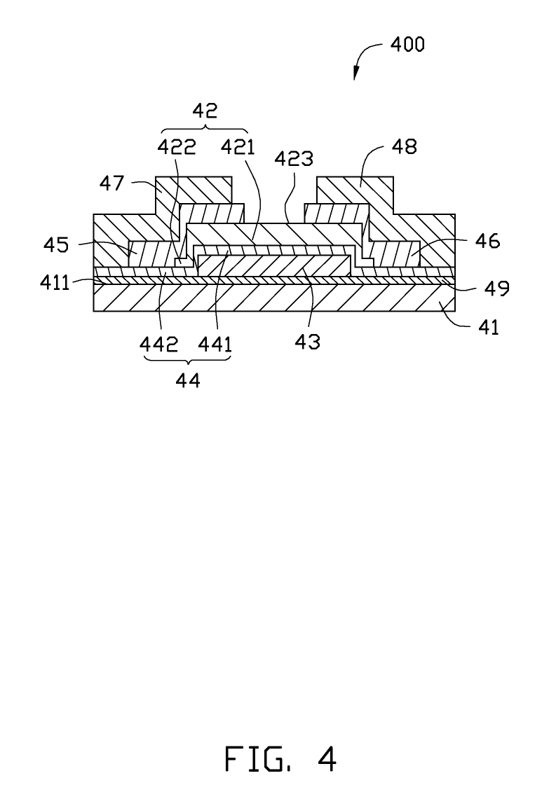

Referring to FIG. 4, a thin film transistor 400 in accordance with a fourth embodiment of the present disclosure is a bottom gate transistor. The thin film transistor 400 includes a substrate 41, an adhering layer 49, a gate electrode 43, a gate insulating layer 44 and a channel region 42 formed in series along a direction from a bottom to a top of the thin film transistor 400. In other words, the adhering layer 49 is formed on the substrate 41, the gate electrode 43 is formed on the adhering layer 49, the gate insulating layer 44 is formed on the gate electrode 43, and the channel region 42 is formed on the gate insulating layer 44. The thin film transistor 400 further includes a source region 45 and a drain region 46 formed on the channel region 42 and spaced from each other, a source electrode 47 formed on the source region 45, and a drain electrode 48 formed on the drain region 46.

The substrate 41 has a top surface 411. The adhering layer 49 is formed on the substrate 41 and the entire adhering layer 49 is attached to the top surface 411 of the substrate 41. The adhering layer 49 can be made of a material selected from a group consisting of glass (such as spin-on glass), SiOₓ, SiO_{y}Nₓ and silicone. The adhering layer 49 can also be made of a metal material selected from Pd, Pt, Al, Au, Ag, In, Ni, Ti, Cr, Mo, W and Ta.

The gate electrode 43 is formed on the adhering layer 49. The gate insulating layer 44 is formed on the adhering layer 49 and the gate electrode 43. The gate insulating layer 44 includes a bulge 441 and a horizontal section 442 extending from a bottom of the bulge 441. The bulge 441 covers the gate electrode 43. The horizontal section 442 contacts the adhering layer 49.

The channel region 42 includes a main body 421 and an extending section 422 extending from a bottom of the main body 421. A top of the main body 421 has a top surface 423 opposite to the gate insulating layer 44. The main body 421 covers the bulge 441 of the gate insulating layer 44. The extending section 422 contacts the horizontal section 442 of the gate insulating layer 44.

The source region 45 and the drain region 46 are formed on the top surface 423 of the channel region 42. The source region 45 and the drain region 46 each have a portion extending downwardly to contact the extending section 422 of the channel region 42 and the horizontal section 442 of the gate insulating layer 44.

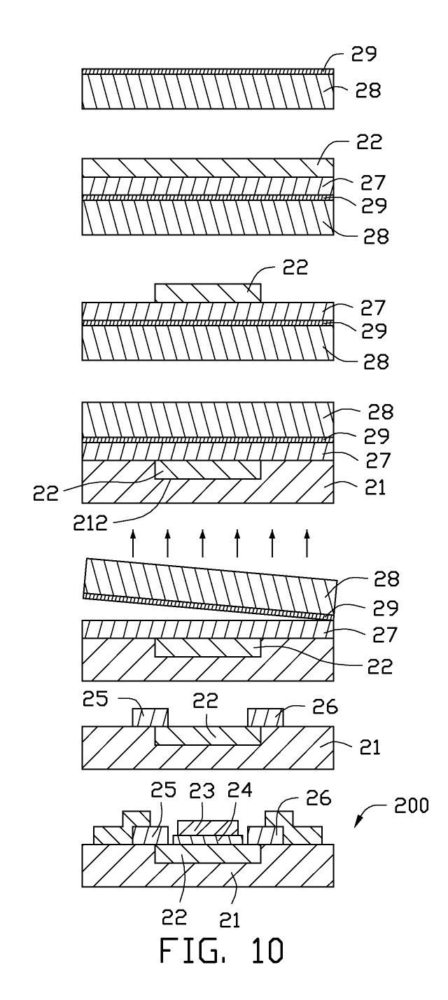

During the formation process of the thin film transistor 400 of the fourth embodiment, a temporary substrate 28 (shown in FIG. 10) can be provided on which the source region 45, the drain region 46, the gate electrode 43 and the channel region 42 are formed, the source region 45, the drain region 46, the gate electrode 43 and the channel region 42 are then transferred on the substrate 41 using the adhering layer 49, and the temporary substrate 28 is removed for forming the source electrode 47 on the source region 45, and the drain electrode 48 on the drain region 46.

Understandably, the adhering layer 49 is not needed if the thin film transistor 400 is formed by depositing layers on the substrate 41 in series.

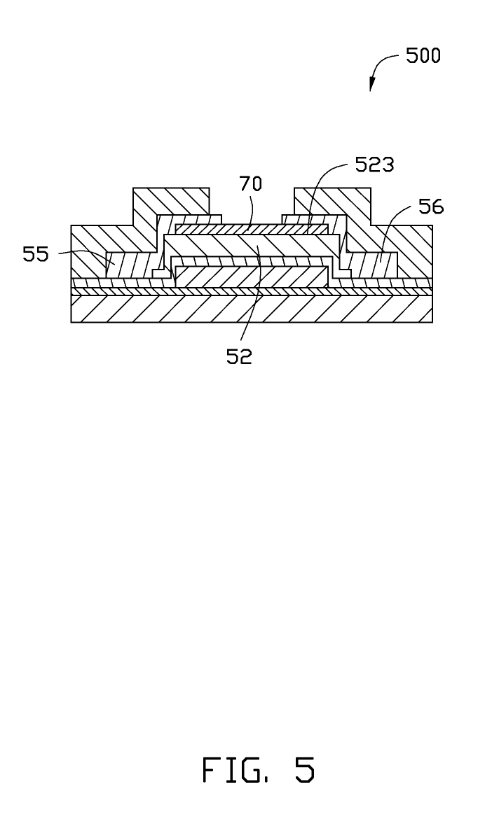

Referring to FIG. 5, a thin film transistor 500 in accordance with a fifth embodiment of the present disclosure is a bottom gate transistor. The thin film transistor 500 is similar to the thin film transistor 400, excepting that a stop layer 70 is further included. The stop layer 70 is formed on a top surface 523 of a channel region 52. The stop layer 70 covers a part of the top surface 523 of the channel region 52 to prevent the part of the top surface 523 from exposing when forming a source region 55 and a drain region 56 on the channel region 52, thus avoiding a contamination of the channel region 52 by plasma, etching solution or lithograpy. The stop layer 70 can be made of SiOₓ or SiNₓ.

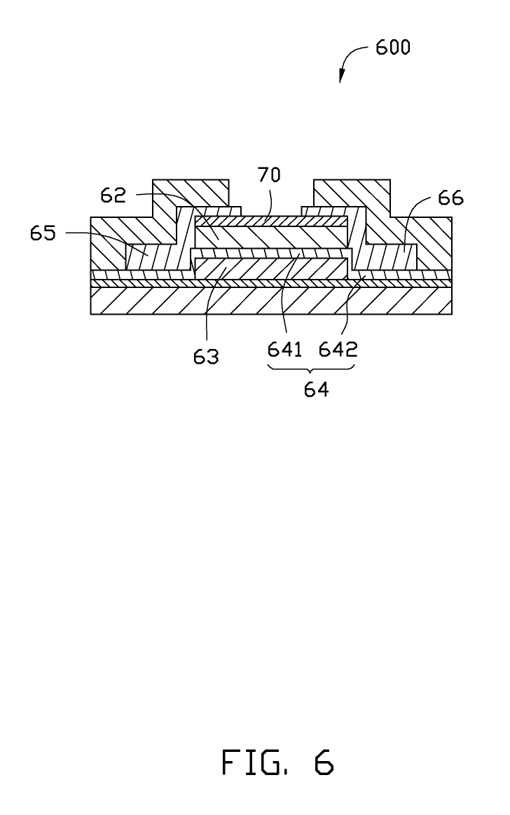

Referring to FIG. 6, a thin film transistor 600 in accordance with a sixth embodiment of the present disclosure is a bottom gate transistor. The thin film transistor 600 is similar to the thin film transistor 500. The differences are that a channel region 62 covers a part of a top surface of a bulge 641 of a gate insulating layer 64, and has no extending section contacting a horizontal section 642 of the gate insulating layer 64. Edges of the channel region 62 and edges of a gate electrode 63 are in alignment with each other. A stop layer 70 completely covers the channel region 62 and edges thereof are in alignment with each other. A source region 65 is formed on the stop layer 70 and extends downwardly to contact the channel region 62, the bulge 641 and the horizontal section 642 of the gate insulating layer 64. A drain region 66 is formed on the stop layer 70 and extends downwardly to contact the channel region 62, the bulge 641 and the horizontal section 642 of the gate insulating layer 64.

In the fifth embodiment, the channel region 52 and the stop layer 70 are formed in two successively steps using two masks, therefore the channel region 52 and the stop layer 70 have edges not aligned with each other. In the sixth embodiment, the channel region 62 and the stop layer 70 are etched in one step using one mask, therefore the stop layer 70 and the channel region 62 have edges aligned with each other.

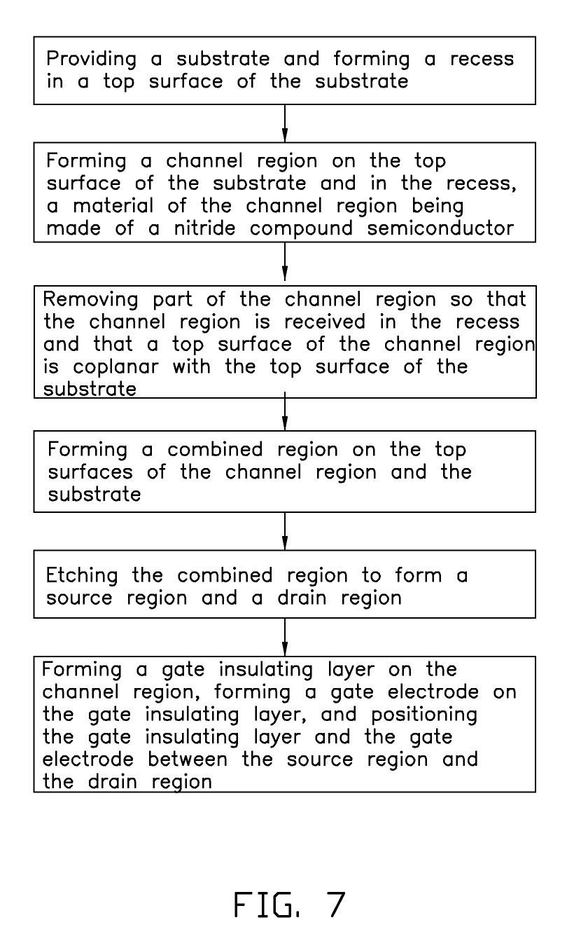

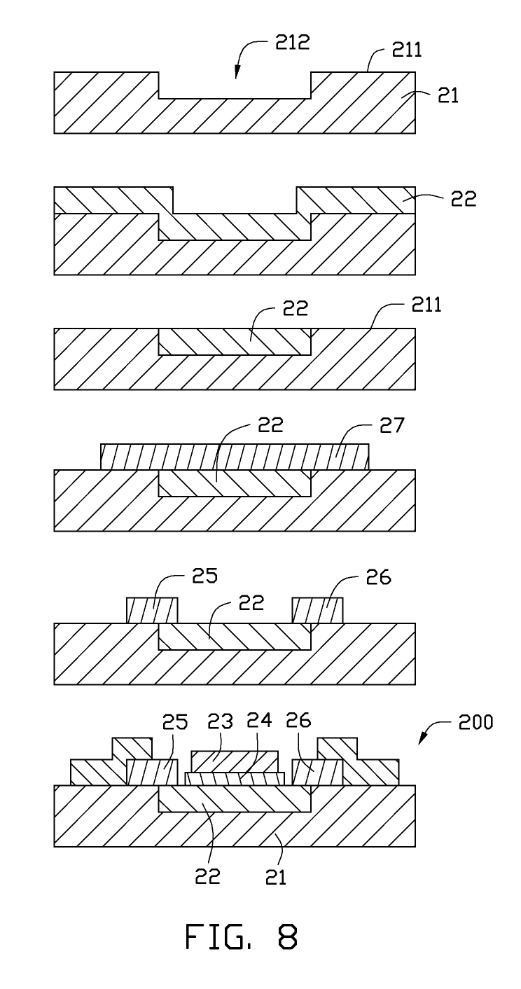

As shown in FIGS. 7 and 8, a method of manufacturing the thin film transistor 200 is also provided. The details of the method are as follows.

Firstly, a substrate 21 is provided. The substrate 21 has a top surface 211. A recess 212 is formed in the top surface 211.

Secondly, a channel region 22 is formed on the substrate 21. The channel region 22 is made of a nitride compound semiconductor. The channel region 22 has a part covering the top surface 211 of the substrate 21 and another part filling in the recess 212.

Thirdly, the part of the channel region 22 covering the top surface 211 of the substrate 21 is removed, and the another part of the channel region 22 filling in the recess 212 is polished. As a result, the channel region 22 is fittingly received in the recess 212 and has a top surface coplanar with the top surface 211 of the substrate 21.

Fourthly, a combined region 27 is formed on the top surface of the channel region 22 and the top surface 211 of the substrate 21.

After that, the combined region 27 is etched to form a source region 25 and a drain region 26. The source region 25 contacts the channel region 22 and covers a part of the top surface 211 of the substrate 21. The drain region 26 contacts the channel region 22 and covers a part of the top surface 211 of the substrate 21.

Then a gate insulating layer 24 is formed on the channel region 22, and a gate electrode 23 is formed on the gate insulating layer 24 opposite to the channel region 22. The gate insulating layer 24 and the gate electrode 23 are positioned between the source region 25 and the drain region 26.

The channel region 22 can be formed on the substrate 21 by a process of CVD, pulse laser deposition, MBE, PVD or sputtering. The channel region 22 being received in the recess 212 has a more stability, and a performance of the thin film transistor 200 is accordingly promoted.

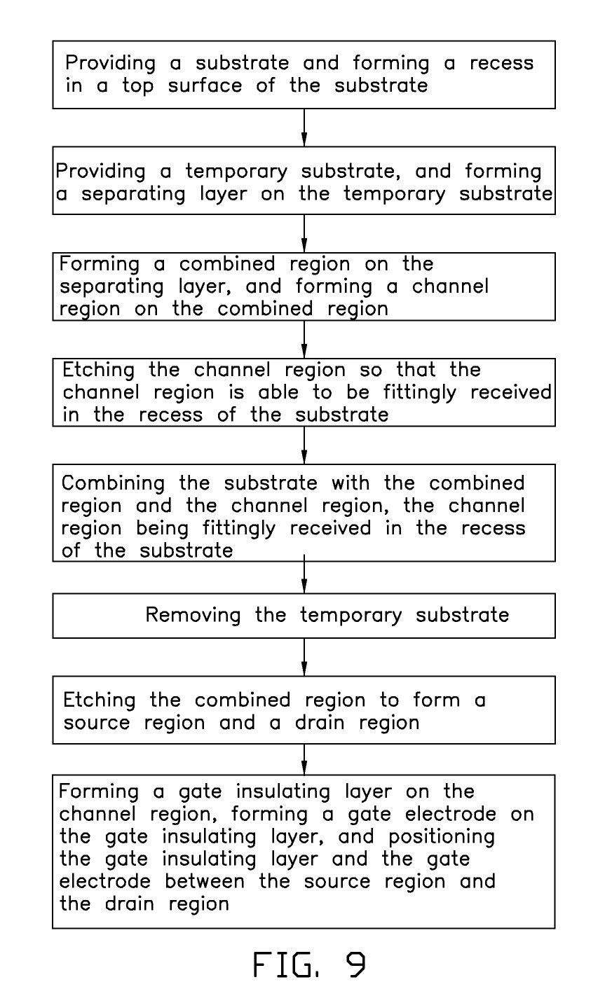

Referring to FIGS. 9 and 10, another method of manufacturing the thin film transistor 200 is provided. Details of the method are as follows.

A substrate 21 is provided. The substrate 21 has a top surface, and a recess 212 is formed in the top surface.

A temporary substrate 28 is provided. A separating layer 29 is formed on the temporary substrate 28.

A combined region 27 is formed on the separating layer 29, and a channel region 22 is formed on the combined region 27 opposite to the separating layer 29. The channel region 22 completely covers the combined region 27. The channel region 22 is made of a nitride compound semiconductor.

The channel region 22 is then etched to be able to be fittingly received in the recess 212 of the substrate 21.

The substrate 21 is combined with the combined region 27, and the channel region 22 is fittingly received in the recess 212 of the substrate 21.

The temporary substrate 28 is removed from the combined region 27 by separating the separating layer 29.

A source region 25 and a drain region 26 are formed by etching the combined region 27.

Then a gate insulating layer 24 is formed on the channel region 22, and a gate electrode 23 is formed on the gate insulating layer 24 opposite to the channel region 22. The gate insulating layer 24 and the gate electrode 23 are positioned between the source region 25 and the drain region 26.

Differing from the method in the previous embodiment, the method of the present embodiment has a temporary substrate 28 with the combined region 27 and the channel region 22 formed thereon. After transferring the structure, which includes the combined region 27 and the channel region 22, onto the substrate 21, the temporary substrate 28 is removed from the combined region 27.

The temporary substrate 28 can be made of sapphire or SiC, and the substrate 21 can be made of glass. The combined region 27 and the channel region 22 can be deposited on the temporary substrate 28 in a higher temperature such as higher than 600 C. Therefore, a better performance of the channel region 22 may be obtained. The combined region 27 and the channel region 22 formed on the temporary substrate 28 can be transferred onto the substrate 21 by a process of wafer bonding. Understandably, the substrate 21 can be made of inorganic material such as metal, plastic. The substrate 21 can also be made of organic material. The substrate 21 can also be a flexible substrate. A laser lift-off, a mechanic polish, or a chemical etching technology (such as a dry chemical etching or a wet chemical etching) can be used to remove the template substrate 28. The method of the present embodiment can form the channel region 22 in a condition which is easy to satisfy, and can obtain the thin film transistor 200 with a more stable and excellent performance The thin film transistors 300, 400, 500 and 600 can be made by such a method provided in the present embodiment.

It is to be further understood that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A thin film transistor comprising:
a substrate;
a channel region and a gate electrode formed on the substrate, the channel region being made of a nitride compound semiconductor;
a gate insulating layer formed between the channel region and the gate electrode;
a source region and a drain region, each of the source region and the drain region being connected to the channel region.

2. The thin film transistor of claim 1, wherein a material of the nitride compound semiconductor is represented by a formula of Al_{(1-x-y)}InₓGa_{y}N, wherein 0≦x≦1, and 0≦y≦1.

3. The thin film transistor of claim 1, wherein the nitride compound semiconductor comprises elements selected from H, C and O.

4. The thin film transistor of claim 1, wherein the nitride compound semiconductor is a doped Al_{(1-x-y)}InₓGa_{y}N, wherein 0≦x≦1, and 0≦y≦1, and Si, Mg or Zn is doped therein.

5. The thin film transistor of claim 2, wherein the nitride compound semiconductor is amorphous, monocrystalline or polycrystalline.

6. The thin film transistor of claim 2, wherein the channel region is attached to the substrate, the gate insulating layer is formed on the channel region, the gate electrode is formed on the gate insulating layer opposite to the channel region, and the gate insulating layer and the gate electrode are between the source region and the drain region.

7. The thin film transistor of claim 6, wherein top surfaces of the source region, the drain region and the channel region are coplanar, and edges of the gate electrode and the gate insulating layer are in alignment with edges of the channel region.

8. The thin film transistor of claim 6, wherein the substrate comprises a recess formed on a top surface of the substrate, the recess being configured to receive the channel region, and a top surface of the channel region and the top surface of the substrate are coplanar.

9. The thin film transistor of claim 8, wherein the source region is formed on the top surface of the substrate and contacts the channel region, and the drain region is formed on the top surface of the substrate and contacts the channel region.

10. The thin film transistor of claim 6, further comprising an adhering layer formed on the substrate, the adhering layer forming a groove configured to receive the channel region, a top surface of the adhering layer and a top surface of the channel region being coplanar, the source region being formed on the top surface of the adhering layer and contacting the channel region, and the drain region being formed on the top surface of the adhering layer and contacting the channel region.

11. The thin film transistor of claim 1, further comprising an adhering layer formed on the substrate, the gate electrode being formed on the adhering layer, the gate insulating layer being formed on the gate electrode opposite to the adhering layer, and the channel region being formed on the gate insulating layer.

12. The thin film transistor of claim 11, wherein the gate insulating layer comprises a bulge covering the gate electrode, and a horizontal section extending from the bulge, the horizontal section being in contact with the adhering layer.

13. The thin film transistor of claim 12, wherein the source region is formed on the channel region and configured to contact the horizontal section of the gate insulating layer, and the drain region is formed on the channel region and configured to contact the horizontal section of the gate insulating layer.

14. The thin film transistor of claim 12, wherein the channel region is formed on the bulge of the gate insulating layer, and edges of the channel region and edges of the gate electrode are in alignment with each other.

15. The thin film transistor of claim 12 further comprising a stop layer formed on a top surface of the channel region, edges of the stop layer and edges of the channel region are in alignment with each other.

16. The thin film transistor of claim 12, wherein the channel region comprises a main body covering the bulge of the gate insulating layer, and an extending section extending from a bottom of the main body and contacting the horizontal section of the gate insulating layer.

17. The thin film transistor of claim 12 further comprising a stop layer formed on a top surface of the channel region, the stop layer partially covering a top surface of the channel region.

18. A method of manufacturing a thin film transistor comprising:
providing a substrate and forming a recess in a top surface of the substrate;
forming a channel region on the top surface of the substrate and in the recess, the channel region being made of a nitride compound semiconductor;
removing a part of the channel region so that the channel region is received in the recess and that a top surface of the channel region is coplanar with the top surface of the substrate;
forming a combined region on the top surface of the channel region and the top surface of the substrate;
etching the combined region to form a source region and a drain region;
forming a gate insulating layer on the channel region;
forming a gate electrode on the gate insulating layer opposite to the channel region; and
positioning the gate insulating layer and the gate electrode between the source region and the drain region.

19. A method of manufacturing a thin film transistor comprising:
providing a substrate and forming a recess in a top surface of the substrate;
providing a temporary substrate, and forming a separating layer on the temporary substrate;
forming a combined region on the separating layer;
forming a channel region on the combined region opposite to the separating layer;
etching the channel region so that the channel region is configured to be received in the recess of the substrate;
combining the substrate with the combined region and the channel region with the channel region in the recess of the substrate;
removing the temporary substrate by separating the separating layer;
etching the combined region to form a source region and a drain region; and
forming a gate insulating layer on the channel region, forming a gate electrode on the gate insulating layer opposite to the channel region, and positioning the gate insulating layer and the gate electrode between the source region and the drain region.

20. The method of claim 19, wherein the step of removing the temporary substrate is carried out by a laser lift-off, a mechanic polish, a dry chemical etching or a wet chemical etching.
